(19) United States
(12) Patent Application Publication
(10) Pub. No.: US 2024/0030155 A1
(43) Pub. Date: Jan. 25, 2024

(54) WAFER LEVEL CHIP SCALE PACKAGE UNIT

(71) Applicant: PANJIT INTERNATIONAL INC., Kaohsiung City (TW)

(72) Inventors: Chung-Hsiung HO, Kaohsiung City (TW); Chi-Hsueh LI, Tainan City (TW); Yu-Ming HSU, Kaohsiung City (TW); Yung-Hui WANG, Kaohsiung City (TW); Chia-Wei CHEN, Kaohsiung City (TW)

(73) Assignee: PANJIT INTERNATIONAL INC., Kaohsiung City (TW)

(21) Appl. No.: 17/884,956

(22) Filed: Aug. 10, 2022

(30) Foreign Application Priority Data
Jul. 20, 2022 (TW) 111127104

(51) Int. Cl. H01L 23/552; H01L 21/56; H01L 23/31; H01L 23/00; H01L 21/78; H01L 23/373

(52) U.S. Cl. CPC H01L 23/552; H01L 21/561; H01L 23/3185; H01L 24/05; H01L 21/78; H01L 23/3735; H01L 24/06; H01L 24/13; H01L 2224/05073; H01L 2224/05573; H01L 2224/05562; H01L 2224/0603; H01L 2224/13023

(57) ABSTRACT

The present invention provides a wafer level chip scale package (WLCSP) unit; the WLCSP unit includes a die, a dielectric layer, and a bottom metal layer; the die has a substrate and an active surface; multiple pads are mounted on the active surface, and a soldering layer is mounted on a surface of each of the pads; the dielectric layer covers an upper part of four lateral surfaces of the die, exposing a lower part of the four lateral surfaces of the die; the bottom metal layer is mounted on a bottom surface of the substrate; the bottom metal layer protects a bottom surface of the dies, dissipates heat generated by the dies, and also protects the dies from external electromagnetic interferences (EMI).

### CROSS-REFERENCE TO RELATED APPLICATIONS

This application claims the priority benefit of TW application serial No. 111127104 filed on Jul. 20, 2022. The entirety of the above-mentioned patent application is hereby incorporated by reference herein and made a part of the specification.

### BACKGROUND OF THE INVENTION

### 1. Field of the Invention

The present invention relates to a wafer level package unit, and more particularly a wafer level chip scale package unit with better heat dissipation and better electromagnetic interference (EMI) protection.

### 2. Description of the Related Art

With reference to FIGS. 6A to 6F, a packaging method of multiple conventional wafer level chip scale package (WLCSP) units is disclosed. In FIG. 6A, multiple dies 502 (as shown with dash lines) are formed on a top surface of a wafer 500. Multiple conductive bulks 504 are mounted on each of the dies 502. The wafer 500 is then diced first time around each of the dies 502, forming multiple dicing lanes 506. The dicing lanes 506 are not fully through the wafer 500.

In FIG. 6B, a molding compound 508 is filled in each of the dicing lanes 506, surrounding the conductive bulks 504 of each of the dies 502, and also surrounding a lower part of each of the conductive bulks 504. After the molding compound 508 is filled, a support film 510 is adhered on the top surface of the wafer 500.

In FIG. 6C, the wafer 500 with the support film 510 is flipped, and a bottom surface of the wafer 500 is grinded to decrease a thickness of the wafer 500. The wafer 500 is grinded until the molding compound 508 in each of the dicing lanes 506 is exposed. As shown in FIG. 6C, L is a thickness of the grinded wafer 500.

In FIG. 6D, after the bottom surface of the wafer 500 is grinded, a back protection layer 512 is adhered onto the bottom surface of the grinded wafer 500. The back protection layer 512 protects a bottom surface of each of the dies 502.

In FIG. 6E, the support film 510 is removed, and the grinded wafer 500 is then diced second time around each of the dies 502. The molding compound 508 is completely diced through, and as a result, multiple WLCSP units 600 are created.

With reference to FIG. 6F, each of the WLCSP units 600 obtained from the aforementioned packaging method includes six-sided protection layers—the molding compound 508 surrounding four lateral surfaces of each of the dies 502, the molding compound 508 mounted on a top surface of each of the dies 502, and the back protection layer 512 mounted on the bottom surface of each of the dies 502.

Since the molding compound 508 or the back protection layer 512 is made of epoxy resin, the six-sided protection layers surrounding each of the dies 502 do not provide adequate heat dissipation. As a result, heat generated by each of the dies 502 is dissipated inefficiently.

### SUMMARY OF THE INVENTION

The present invention provides a wafer level chip scale package (WLCSP) unit with better heat dissipation and better electromagnetic interference (EMI) protection.

The WLCSP unit of the present invention includes a die, a dielectric layer, and a bottom metal layer. The die has a substrate and an active surface. Multiple pads are mounted on the active surface, and a surface of each of the pads includes a soldering layer. The dielectric layer covers an upper part of each of four lateral surfaces of the die, leaving a lower part of each of the four lateral surfaces of the die exposed. The dielectric layer also covers the active surface of the die, and a surface of the dielectric layer and the surface of each of the pads are on a same surface level. The bottom metal layer is mounted on a bottom surface of the substrate.

A packaging method of a WLCSP unit includes the following steps:
providing a substrate and mounting multiple dies on the substrate, wherein each of the dies includes an active surface, and multiple pads are mounted on the active surface of each of the dies;
mounting a bottom metal layer on a bottom surface of the substrate;
dicing the substrate for a first time along and around each of the dies to form multiple dicing lanes, wherein the dicing lanes are only partly through the substrate;
filling a dielectric layer in each of the dicing lanes, wherein the dielectric layer covers the active surface of each of the dies, and a surface of the dielectric layer and a surface of each of the pads are on a same surface level;
dicing the substrate for a second time along and around each of the dies to completely dice through the substrate and the bottom metal layer, and to separate the dies into multiple WLCSP units; wherein a dicing width of dicing the second time is less than a dicing width of dicing the first time; wherein each of the WLCSP units is surrounded by the dielectric layer, and a bottom surface of each of the WLCSP units includes the bottom metal layer.

Each of the WLCSP units of the present invention includes the bottom metal layer. The bottom metal layer protects a bottom surface of each of the dies, and allows heat generated by each of the dies to be dissipated outwards. Furthermore, in comparison to dielectric materials such as epoxy resin, the bottom metal layer is able to provide better EMI protection, shielding each of the WLCSP units from external electromagnetic interferences.

### BRIEF DESCRIPTION OF THE DRAWINGS

FIGS. 1A to 1J are perspective views of a flow chart for a first embodiment of a packaging method of the present invention.

FIG. 2 is a three dimensional cross-sectional view of a wafer level chip scale package unit of the present invention.

FIG. 3 is a cross-sectional view of the wafer level chip scale package unit in another embodiment of the present invention.

FIGS. 4A to 4K are perspective views of a flow chart for a second embodiment of the packaging method of the present invention.

FIGS. 5A to 5J are perspective views of a flow chart for a third embodiment of the packaging method of the present invention.

FIGS. 6A to 6F are perspective views of a flow chart for a packaging method for multiple conventional wafer level chip scale package (WLCSP) units.

### DETAILED DESCRIPTION OF THE INVENTION

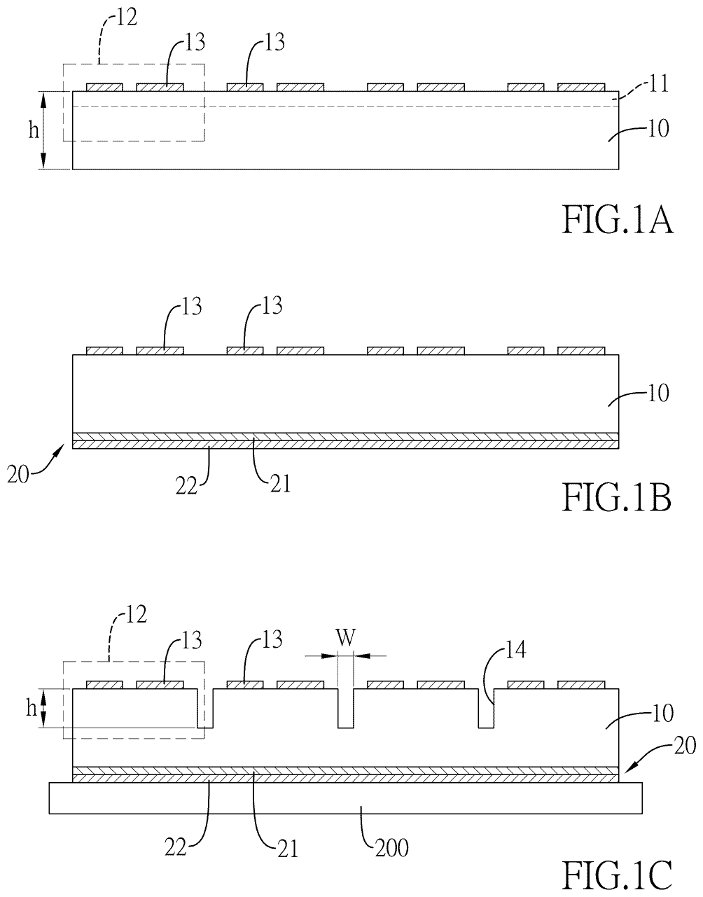

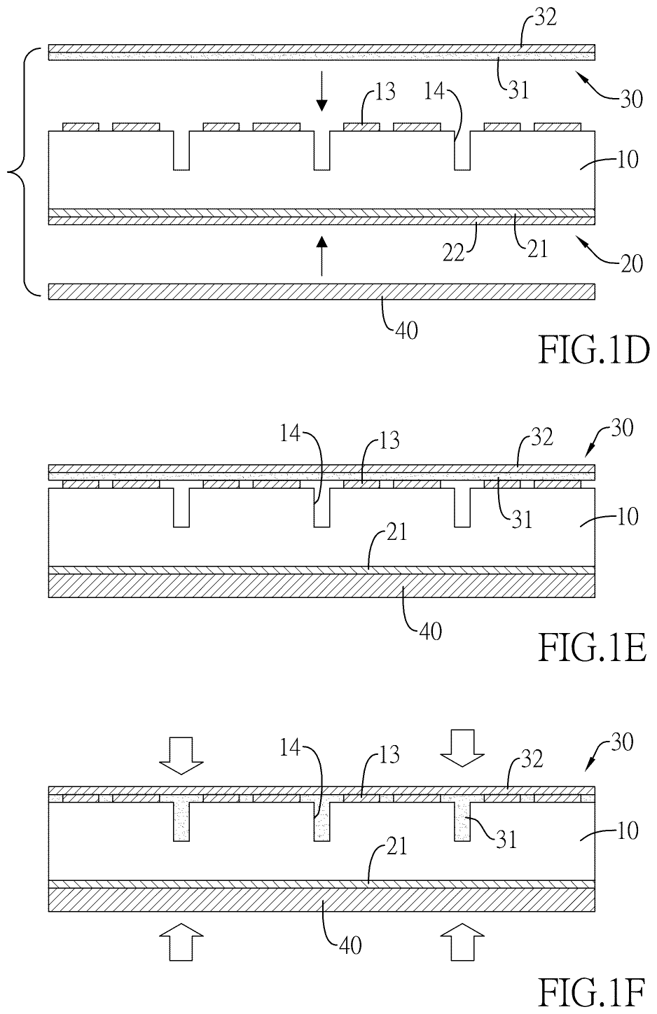

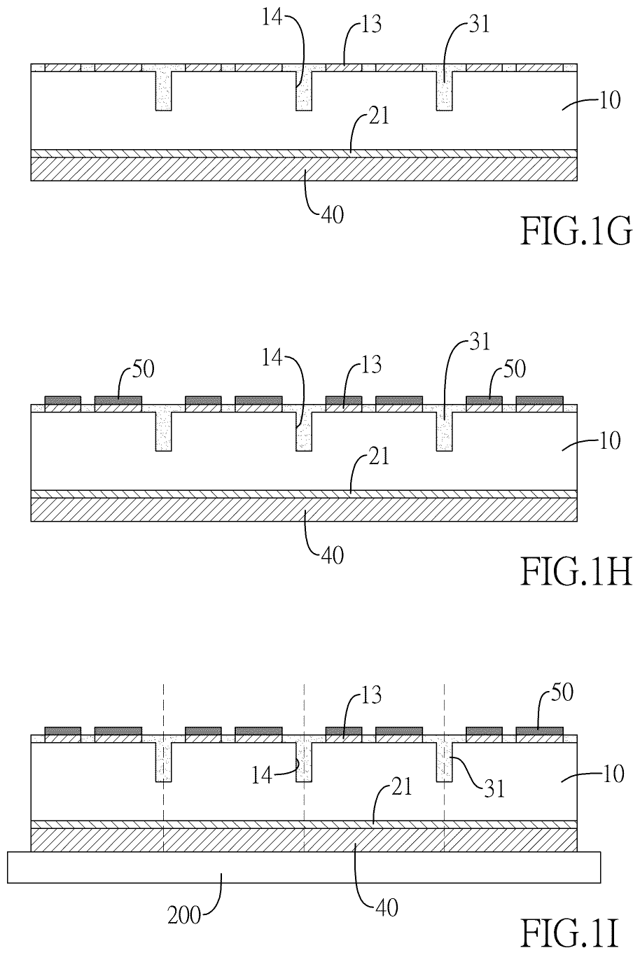

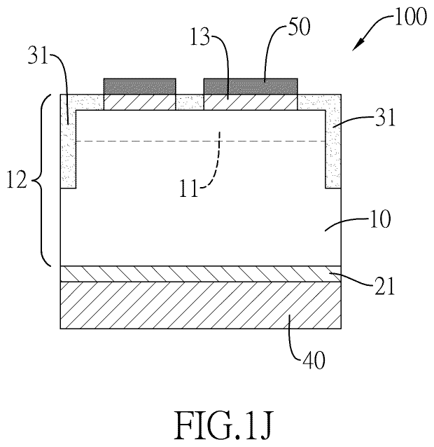

With reference to FIGS. 1A to 1H, a first embodiment of a packaging method of the present invention is shown. With reference to FIG. 1A, a substrate 10 is provided, wherein a thickness of the substrate is h. Multiple dies 12, such as active device dies/chips as denoted by dash-lined-boxes, are mounted on the substrate 10. The substrate 10 is a wafer, and a material for the substrate 10 may be silicon (Si) or other semiconductor materials. An epitaxy layer 11 is formed on the substrate 10. A component area of each of the dies 12 may be produced inside of the epitaxy layer 11. A surface of the epitaxy layer 11 is an active surface of each of the dies 12. Multiple pads 13 are mounted on the active surface of each of the dies 12.

With reference to FIG. 1B, a first metal layer 20 is mounted on a bottom surface of the substrate 10. In an embodiment of the present invention, the first metal layer 20 is a single material metal layer (such as a copper layer), or a composite metal layer. The first metal layer 20 is mounted on the bottom surface of the substrate 10 by deposition or electroplating. In the case of the first metal layer 20 being the composite metal layer, the composite metal layer includes a titanium (Ti) layer 21 mounted on the bottom surface of the substrate 10, and a copper layer 22 mounted on the titanium layer 21.

With reference to FIG. 1C, mount a support film 200 on the bottom surface of the substrate 10, and dice the substrate 10 for a first time. A possible dicing method used by the present invention includes dry etching with suitable etching agents, wet etching, asymmetrical etching, or plasma etching. Another possible dicing method used by the present invention may also include laser dicing, or mechanical dicing with a blade to a desired dicing depth. When dicing the substrate 10 for the first time, the present invention partially dices the substrate 10 along and around each of the dies 12, creating multiple dicing lanes 14 without fully dicing through the substrate 10. A vertical depth d of the dicing lanes 14 is less than or equal to a thickness h of the substrate 10, in other words, d≤h. In an embodiment of the present invention, each of the dicing lanes 14 created by dicing the substrate 10 for the first time has a dicing width W, wherein the dicing width W is, for example, 40 μm.

With reference to FIGS. 1D and 1E, a thermoforming layer 30 is adhered to a top surface of the substrate 10. The thermoforming layer 30 is a composite structure including a dielectric layer 31 and an isolation layer 32. When the thermoforming layer is adhered, the dielectric layer 31 faces the top surface of the substrate 10, and the isolation layer 32 is adhered to another surface of the dielectric layer 31. The dielectric layer 31 is made of materials such as Polypropylene (PP), Ajinomoto build-up film (ABF), etc. The isolation layer 32 is made of material such as copper foil.

A second metal layer 40 is mounted on the bottom surface of the substrate 10. The second metal layer 40 is made of, for example, copper. Depending on a requirement for a product, a thickness of the second metal layer 40 is greater than a thickness of the copper layer 22. For example, the thickness of the second metal layer 40 is 20 μm to 200 μm. Since the second metal layer 40 and the copper layer 22 are both made of copper, for the rest of figures after FIG. 1E, the second metal layer 40 and the copper layer 22 are simplified to be shown as the second metal layer 40.

With reference to FIG. 1F, after respectively adhering the thermoforming layer 30 and the second metal layer 40 onto the top surface and the bottom surface of the substrate 10, the substrate 10 is moved to a thermoforming device with suitable pressure and temperature, and both the top surface and the bottom surface of the substrate 10 are thermoformed as the substrate 10 is thermoformed. By thermoforming, the dielectric layer 31 would melt and fill into each of the dicing lanes 41, and thus the melted dielectric layer 31 covers the active surface of each of the dies 12. When thermoforming, the isolation layer 32 shields the dielectric layer 31 so that the dielectric layer 31 avoids contacting the thermoforming device. Furthermore, the isolation layer 32 restricts flowing direction of the dielectric layer 31 so that the dielectric layer 31 is able to fill into the dicing lanes.

With reference to FIG. 1G, after thermoforming, the isolation layer 32 is removed from the substrate 10, for example, removing the isolation layer 32 by wet etching, and thus exposing the pads 13 of each of the dies 12. After removing the isolation layer 32, a surface of the dielectric layer 31 and a surface of each of the pads 13 are on a same surface level. Furthermore, the dielectric layer 31 between any of the adjacent pads 13 is able to insulate the adjacent pads 13 from each other.

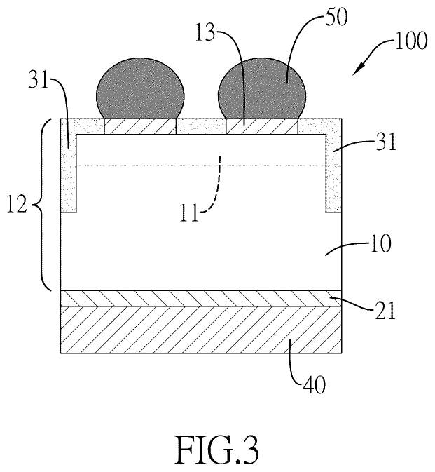

With reference to FIG. 1H, a soldering layer 50 is mounted on a surface of each of the pads 13. In the present embodiment, the soldering layer is a metal protection film. The metal protection film is mounted on the surface of each of the pads 13 through methods such as electroless plating (E′less), electroless nickel immersion gold (ENIG) etc. With reference to FIG. 3, in another embodiment of the present invention, the soldering layer 50 is conductive solder balls on the pads 13 and electrically connected to the pads 13.

With reference to FIGS. 11 and 1J, another support film 200 is adhered to the back of the substrate 10, and the substrate 10 is diced for a second time. As such, multiple wafer level chip scale package (WLCSP) units 100 are created. For dicing the substrate 10 the second time, the substrate 100 is completely diced through along the dicing lanes 41. A dicing width of dicing the second time is less than the dicing width W of each of the dicing lanes 41. For example, for dicing the substrate 10 the second time, a blade with a 20 μm blade width is used along the dicing lanes 14 of 40 μm dicing width, thus leaving nearly 10 μm thickness of the dielectric layer 31 around four lateral surfaces of each of the WLCSP units 100. This way the dielectric layer 31 is able to fully protect the epitaxy layer 11 within each of the dies 12.

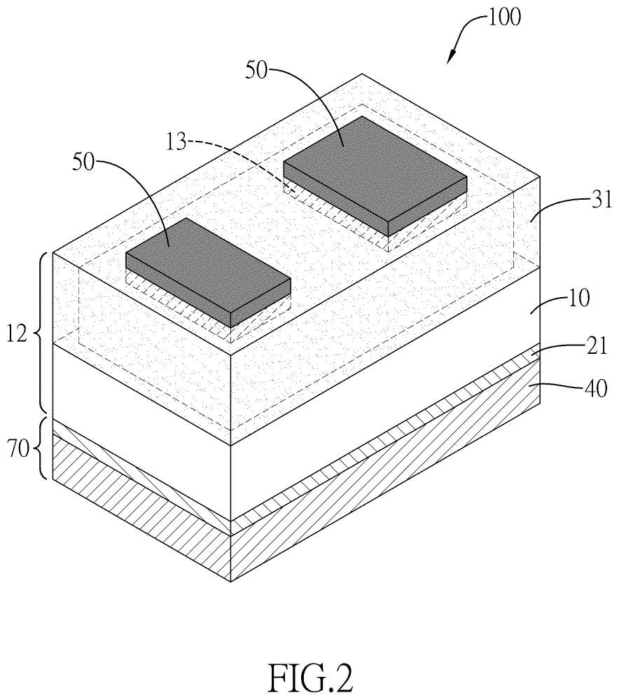

With reference to FIG. 2, a structure of each of the WLCSP units 100 includes a die 12, a dielectric layer 31, and a bottom metal layer 70. The die 12 has a substrate 10 and an active surface. Multiple pads 13 are mounted on the active surface, and a surface of each of the pads 13 includes a soldering layer 50. The dielectric layer 31 covers each of four lateral surfaces of the die 12 and the active surface of the die 12. More particularly, the dielectric layer 31 covers an upper part of each of the four lateral surfaces of the die 12, and the dielectric layer 31 leaves a lower part of each of the four lateral surfaces of the die 12 exposed. The lateral surfaces of the dielectric layer 31 and an exposing part of the lateral surfaces of the substrate 10 are on a same surface level. A surface of a part of the dielectric layer 31 on the active surface and a surface of each of the pads 13 are also on a same surface level. Furthermore, the bottom metal layer 70 is mounted on a bottom surface of the dies 12, and a surface area of the bottom metal layer 70 is equal to a surface area of the bottom surface of the dies 12.

In the present embodiment, the bottom metal layer 70 is a metal layer made of a single material. Two of the pads 13 mounted on the active surface of the die 12 have different dimensions, wherein one of the pads 13 has a bigger surface area on the active surface of the die 12 than the other one of the pads 13. In another embodiment, the bottom metal layer 70 is a composite metal layer. For example, respectively mount a titanium layer 21 and a copper layer 40 on the bottom surface of the substrate 10. A thickness of the titanium layer 21 is thinner than a thickness of the copper layer 40. The bottom metal layer 70 not only serves as holder for the dies 12, but also protects the bottom surface of the dies 12. Furthermore, in comparison to prior arts, heat generated from the dies 12 can be more easily transferred to the bottom metal layer 70 and then dissipated outwards from the bottom metal layer 70 in the present invention. In comparison to dielectric materials such as epoxy resin, the bottom metal layer 70 of the present invention is able to better shield and protect the dies 12 from external electromagnetic interferences.

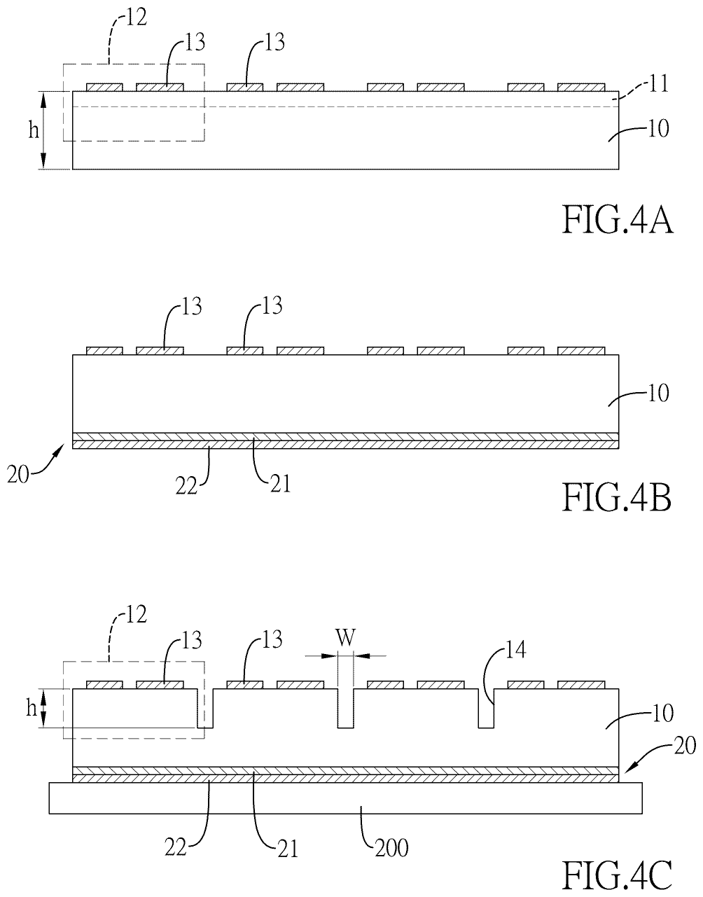

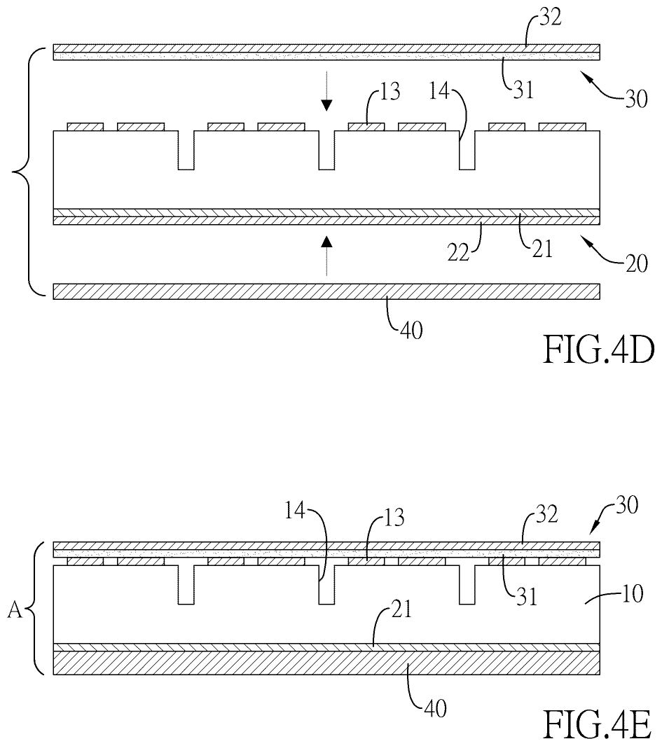

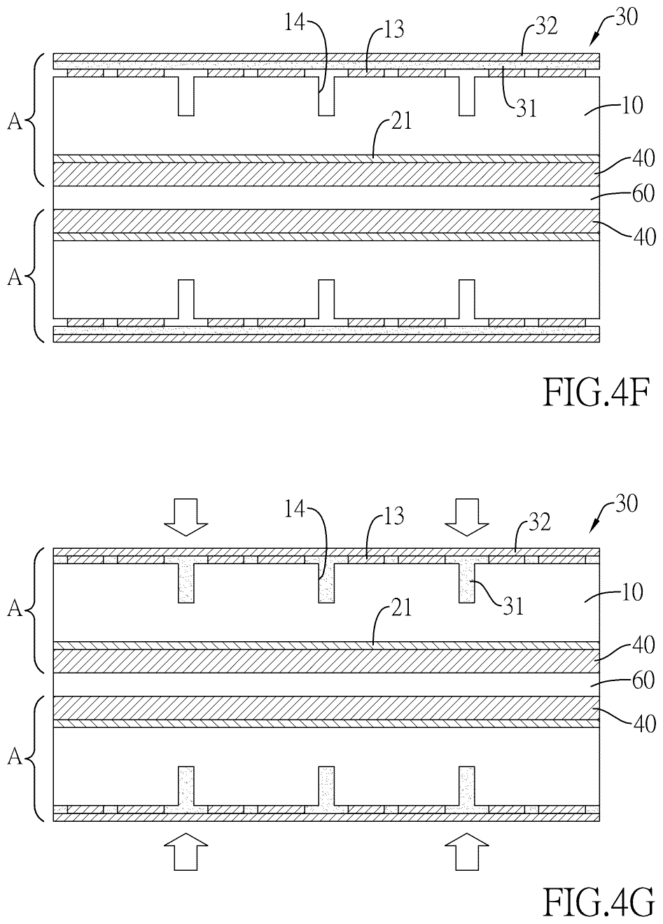

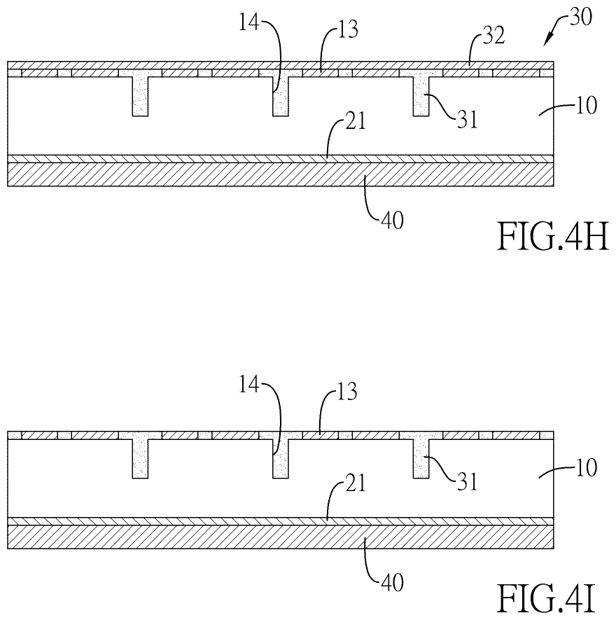

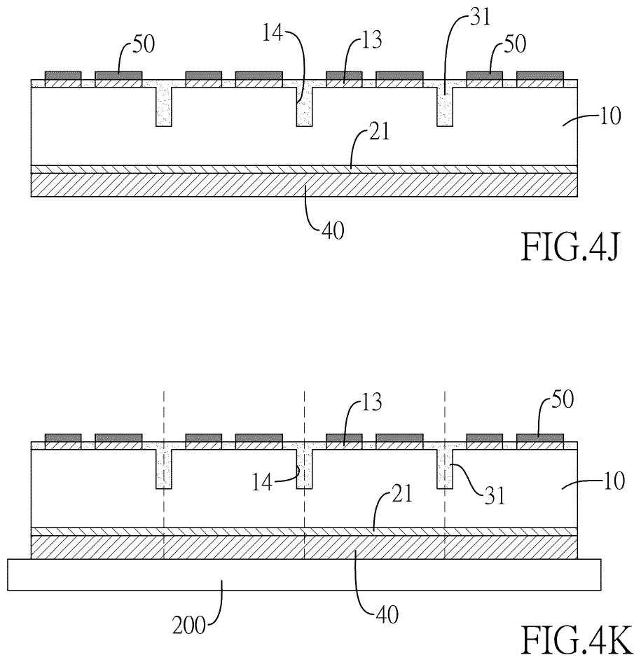

With reference to FIGS. 4A to 4K, a second embodiment of the packaging method of the present invention is shown. FIGS. 4A to 4E show the same packaging steps depicted in FIGS. 1A to 1E and are therefore omitted from repetitive descriptions. Upon completing the packaging step described in FIG. 4E, the substrate 10 adhered with the thermoforming layer 30 and the second metal layer 40 is called a wafer unit A.

With reference to FIG. 4F, two wafer units A are adhered back-to-back, wherein a connection layer 60 with double-sided adhesive adheres to the second metal layer 40 of each of the wafer units A. In the present embodiment, the connection layer 60 is a thermal release film.

With reference to FIG. 4G, after adhering the two wafer units A, the connection layer 60 is thermoformed. By thermoforming, the dielectric layer 31 of each of the wafer units A would melt, flow, and fill into each of the dicing lanes 14 and cover the active surface of each of the dies 12. In the present embodiment, by adhering two wafer units A, an overall thickness for thermoforming is increased, and therefore when thermoforming as shown in FIG. 4G, the two wafer units A are more cushioned and have less chance of breaking. As such, the packaging method of the present invention is able to increase yield of the wafer units A.

With reference to FIG. 4H, after thermoforming, the two wafer units A are removed from the connection layer 60.

With reference to FIG. 4I, the isolation layer 32 of each of the two wafer units A is also removed, by, for example, wet etching the isolation layer 32 away to expose the pads 13 of each of the dies 12. The dielectric layer 31 on the active surface of each of the dies 12 would roughly have same surface level with a surface of each of the pads 13.

With reference to FIG. 4J, a soldering layer 50 is formed on the surface of each of the pads 13 on each of the dies 12. In the present embodiment, the soldering layer 50 is a metal protection film. The soldering layer 50 is mounted on the surface of each of the pads 13 through methods such as electroless plating (E′less), electroless nickel immersion gold (ENIG), etc. With reference to FIG. 3, in another embodiment of the present invention, the soldering layer 50 is conductive solder balls on the pads 13 and is electrically connected to the pads 13.

With reference to FIG. 4K, another support film is adhered to the back of the substrate 10, and the substrate 10 is then diced second time to create multiple WLCSP units 100. For dicing the substrate 10 the second time, the substrate 100 is completely diced through along the dicing lanes 41. A dicing width of a dicing blade for dicing the second time is less than the dicing width W of each of the dicing lanes 41. This way the dielectric layer 31 is able to surround each of the diced WLCSP units 100 with a structure as shown in FIG. 2 or FIG. 3.

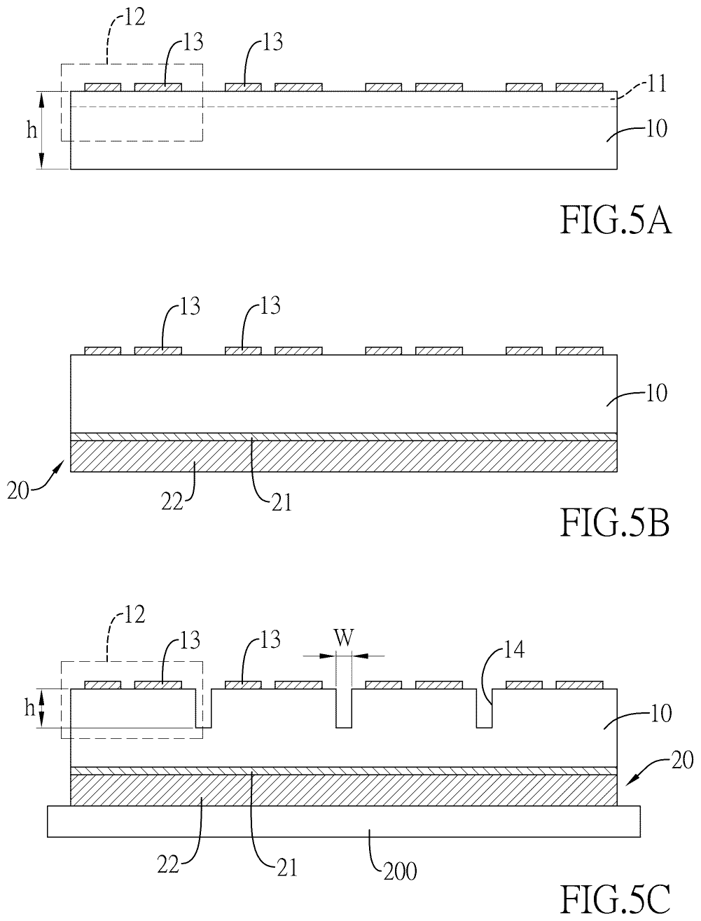

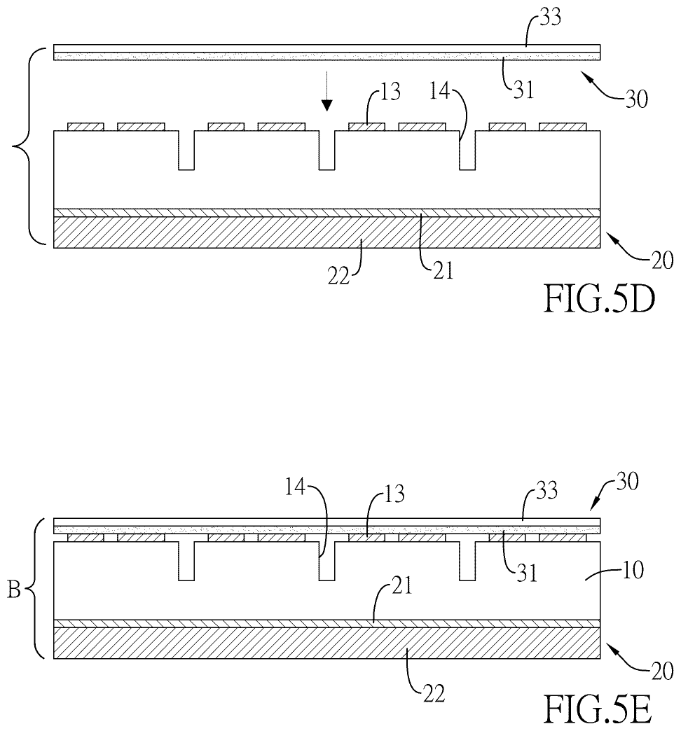

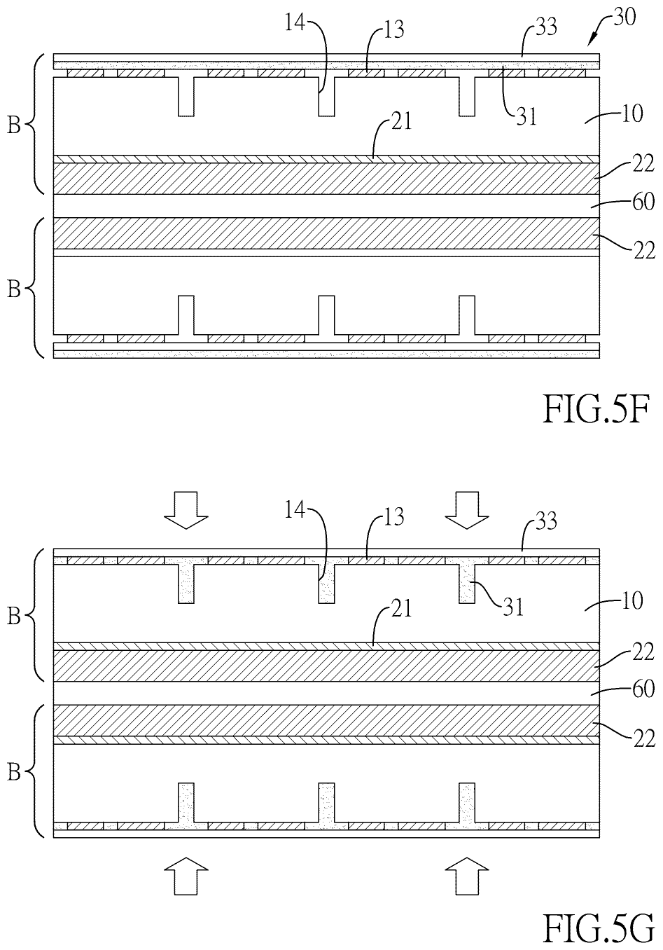

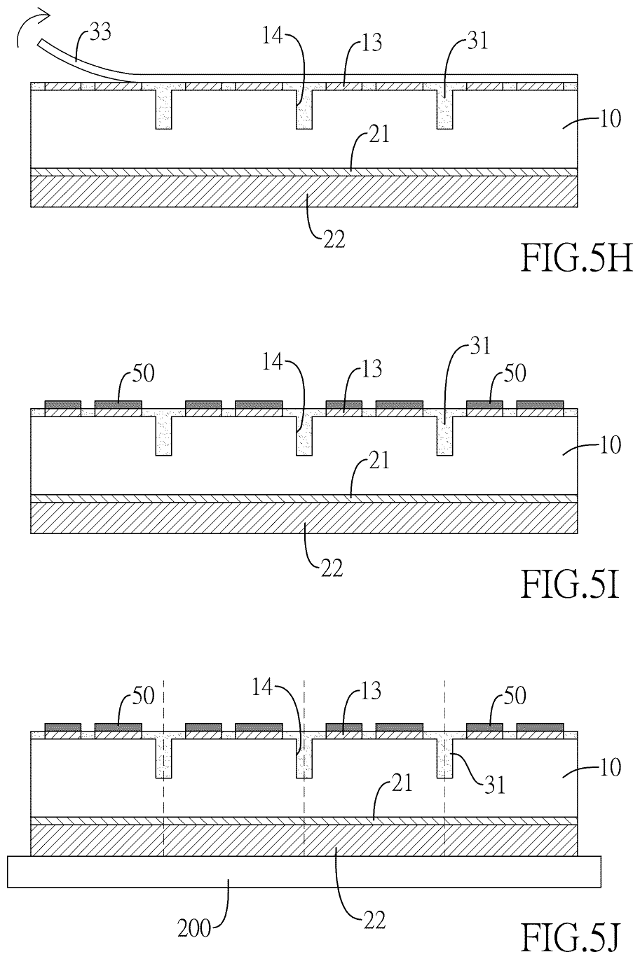

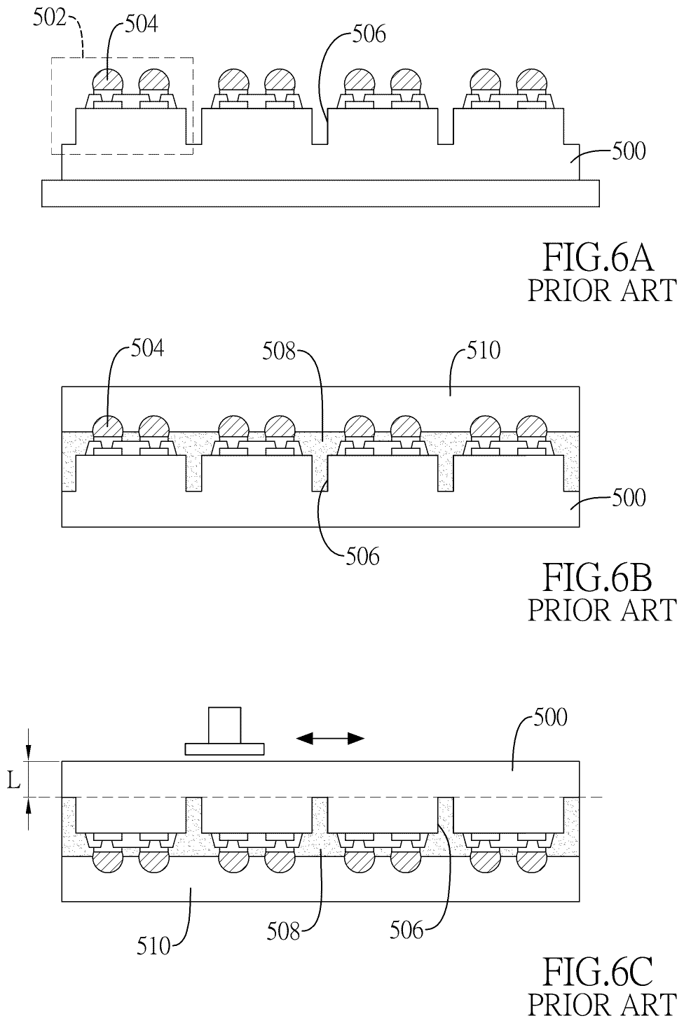

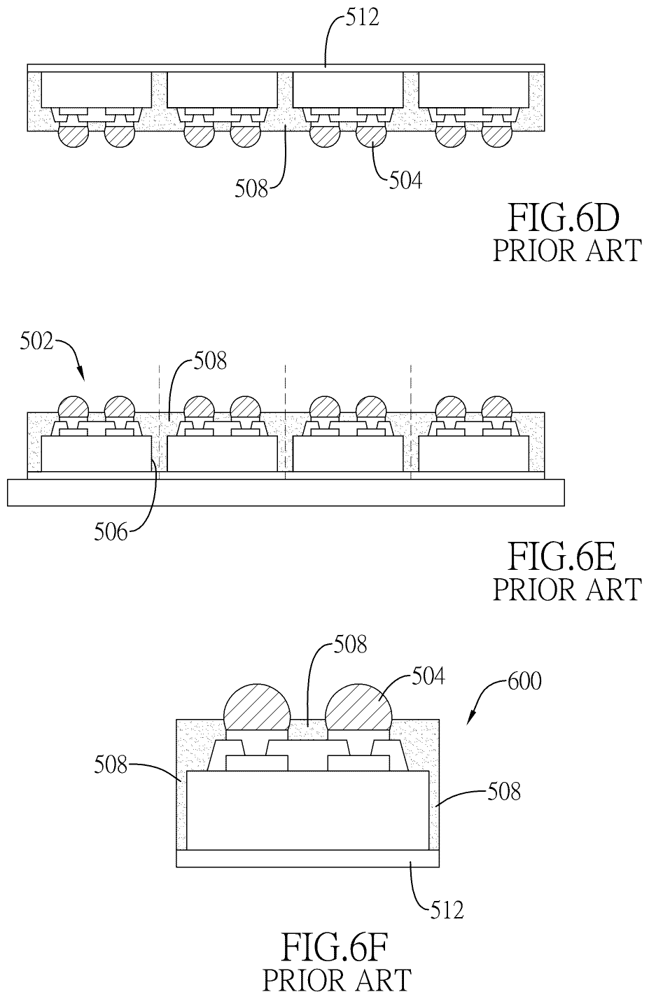

With reference to FIGS. 5A to 5J, a third embodiment of the packaging method of the present invention is shown. With reference to 5A, a substrate 10 is prepared with a thickness h. Multiple dies 12, or active device dies/chips as denoted by dash-lined-boxes, are mounted on the substrate 10. More particularly, an epitaxy layer 11 is first mounted on the substrate 10, the dies 12 are then mounted on the epitaxy layer 11, and then multiple pads 13 are mounted on an active surface of each of the dies 12.

With reference to FIG. 5B, a first metal layer 20 is mounted on a bottom surface of the substrate 10. In an embodiment of the present invention, the first metal layer 20 is a composite metal layer. The composite metal layer includes a titanium layer 21 and a copper layer 22 respectively mounted on the bottom surface of the substrate 10. The first metal layer 20 may be mounted on the bottom surface of the substrate 10 through deposition or electroplating. A thickness of the first metal layer 20 may require a production of the copper layer 22 with 20 μm to 200 μm thickness.

With reference to FIG. 5C, a support film is mounted on the bottom surface of the substrate 10, and the substrate 10 is diced for the first time. When dicing the substrate 10 for the first time, the present invention partially dices the substrate 10 along and around each of the dies 12, creating multiple dicing lanes 14 without fully dicing through the substrate 10. A vertical depth d of the dicing lanes 14 is less than or equal to a thickness h of the substrate 10, in other words, d≤h.

With reference to FIG. 5D, adhere a thermoforming layer 30 on a top surface of the substrate 10. The thermoforming layer 30 includes a dielectric layer 31 and a separation film 33. When adhering the thermoforming layer 30 onto the top surface of the substrate 10, the dielectric layer 31 is adhered to the top surface of the substrate 10, and the separation film 33 is then mounted on a surface of the dielectric layer 31. In this embodiment, the dielectric layer 31 is ABF. In comparison to the first embodiment and the second embodiment, the second metal layer is omitted on the bottom surface of the substrate 10 in the present embodiment.

With reference to FIG. 5E, the substrate 10 with the adhered thermoforming layer 30 is defined as a wafer unit B.

With reference to FIG. 5F, two wafer units B are adhered back-to-back, wherein a connection layer 60 with double-sided adhesive adheres to the copper layer 22 of each of the wafer units B. In this embodiment, the connection layer 60 is a thermal release film.

With reference to FIG. 5G, after adhering the two wafer units B, the connection layer 60 is thermoformed. By thermoforming, the dielectric layer 31 of each of the wafer units B would melt, flow, and fill into each of the dicing lanes 14 and cover the active surface of each of the dies 12. In the present embodiment, by adhering two wafer units B, an overall thickness for thermoforming is increased, and therefore when thermoforming, the two wafer units B are more cushioned and have less chance of breaking.

With reference to FIG. 5H, after thermoforming, the two wafer units B are removed from the connection layer 60. The separation film 33 is also removed from each of the two wafer units B to expose the pads 13 on each of the dies 12. The dielectric layer 31 on the active surface of each of the dies 12 would roughly have same surface level with a surface of each of the pads 13.

With reference to FIG. 5I, a soldering layer 50 is formed on the surface of each of the pads 13 on each of the dies 12. In the present embodiment, the soldering layer 50 is a metal protection film. The soldering layer 50 is mounted on the surface of each of the pads 13 through methods such as electroless plating (E'less), electroless nickel immersion gold (ENIG), etc. With reference to FIG. 3, in another embodiment of the present invention, the soldering layer 50 is conductive solder balls on the pads 13 and is electrically connected to the pads 13.

With reference to FIGS. 5J and 5K, another support film is adhered to the back of the substrate 10, and the substrate 10 is then diced second time to create multiple WLCSP units 100. For dicing the substrate 10 the second time, the substrate 100 is completely diced through along the dicing lanes 41. A dicing width of a dicing blade for dicing the second time is less than the dicing width W of each of the dicing lanes 41. This way the dielectric layer 31 is able to surround each of the diced WLCSP units 100 with a structure as shown in FIG. 2 or FIG. 3.

In conclusion, the packaging method of the present invention creates the shown in FIGS. 2 and 3 with the aforementioned different embodiments of the present invention. Regardless of being mounted through adhesion, electroplating, or deposition, the bottom metal layer 70 would protect the bottom surface of the dies 12, and the bottom metal layer 70 would dissipate heat generated by the dies 12 outwards. Furthermore, in comparison to dielectric materials such as epoxy resin, the bottom metal layer 70 can better protect the dies 12 from external EMI. The dielectric layer 31 also surrounds the four lateral surfaces of each of the dies 12 and covers the active surface of each of the dies 12.

The aforementioned embodiments serve to demonstrate several possible embodiments of the present invention, rather than imposing limitations to the present invention. Any person skilled in related technical field is able to make equivalent changes to the aforementioned embodiments of the present invention. However, all equivalent changes are all encompassed by what is claimed for the present invention.

What is claimed is:

1. A wafer level chip scale package unit, comprising:
a die, having a substrate and an active surface; wherein multiple pads are mounted on the active surface, and a soldering layer is mounted on each of the pads;
a dielectric layer, covering an upper part of four lateral surfaces of the die, exposing a lower part of the four lateral surfaces of the die; wherein the dielectric layer also covers the active surface of the die, and a surface of the dielectric layer and a surface of each of the pads are on a same surface level;
a bottom metal layer, mounted on a bottom surface of the substrate; wherein a surface area of the bottom metal layer is equal to a surface area of a bottom surface of the die.

2. The wafer level chip scale package unit as claimed in claim 1, wherein:
the bottom metal layer is a metal layer made of a single material.

3. The wafer level chip scale package unit as claimed in claim 1, wherein:
the bottom metal layer is a composite metal layer made of different materials.

4. The wafer level chip scale package unit as claimed in claim 3, wherein the bottom metal layer comprises a titanium layer and a copper layer respectively mounted on the bottom surface of the substrate.

5. The wafer level chip scale package unit as claimed in claim 4, wherein:
a thickness of the titanium layer is thinner than a thickness of the copper layer.

6. The wafer level chip scale package unit as claimed in claim 3, wherein:
the dielectric layer surrounding the four lateral surfaces of the die has same surface level as exposing lateral surfaces of the substrate.

7. The wafer level chip scale package unit as claimed in claim 1, wherein:
the soldering layer mounted on each of the pads is a conductive solder ball electrically connected to each of the pads.

8. The wafer level chip scale package unit as claimed in claim 1, wherein:
two of the pads mounted on the active surface of the die have different dimensions.
